(19) United States
(12) Patent Application Publication
(10) Pub. No.: US 2025/0080163 A1
(43) Pub. Date: Mar. 6, 2025

(54) AUTOMATIC TRAINING OF ECHO CANCELLER IN UPSTREAM SIGNAL RECEIVERS ON QUIET SUBCARRIERS

(71) Applicant: Avago Technologies International Sales Pte. Limited, Singapore (SG)

(72) Inventors: Hagay Garti, Beer Yaakov (IL); Yitshak Ohana, Givat Zeev (IL)

(73) Assignee: Avago Technologies International Sales Pte. Limited, Singapore (SG)

(21) Appl. No.: 18/460,757

(22) Filed: Sep. 5, 2023

(51) Int. Cl. H04B 3/23; H03H 21/00

(52) U.S. Cl. CPC H04B 3/238; H03H 21/0027

(57) ABSTRACT

The systems and methods described provide a solution for automatic training of echo canceller (EC) in upstream signal receivers on sub-carriers experiencing low activity in the upstream communication. The solution can include one or more processors identifying a plurality of bins (e.g., EC bins). Each bin of the plurality of bins can correspond to a portion of a frequency range of a cable line. The one or more processors can determine that a power level of an echo signal of each of a bin of the plurality of bins and one or more bins adjacent to the bin exceed a respective threshold for the power level. The one or more processors can train an echo canceller of the echo signal for the bin, responsive to the determining.

### TECHNICAL FIELD

This disclosure generally relates to systems and methods of providing echo cancellation in signal receivers, including without limitation, providing training of echo cancellers in upstream signal receivers on quiet subcarriers.

### BACKGROUND

Network communications can be implemented via a variety of mediums or infrastructure, including, for example, fiber optics, coaxial cables or a combination of the two, including for example, hybrid fiber-coaxial (HFC) infrastructure for a data over cable service interface specification (DOCSIS) communication. Such infrastructure can support a number of subchannels for allowing data communication, which can sometimes experience challenges due to echo signals.

### SUMMARY

When there is an upstream signal (US) present in network infrastructures, such as hybrid Fiber-Coaxial (HFC) infrastructures supporting DOCSIS 4.0 full duplex (FDX) communication, training echo cancellers (ECs) for echo signal reduction can be challenging. In such settings, echo cancellers can struggle to train successfully, resulting in communication issues. In DOCSIS 4.0, for example, echo canceller training may not be available during periods of significant correlation between the downstream (DS) signal and residual noise, which could result in cancellation depth loss. During periods of high upstream (US) activity, a lack of training opportunities can impede echo cancellation performance, adversely affecting communication quality and hindering end-user experience.

The present solution overcomes these challenges by allowing for automatic training of the echo canceller of the system during low activity times (e.g., quiet periods) in the upstream subcarriers. These intervals of low activity can include Echo Canceller Training Opportunities (ECTO) as defined in DOCSIS 4.0, or other intervals of low activity, such as calm periods between ECTO periods. The echo canceller can predict and cancel echoes during time durations or periods with high US activity, by training during the low US activity periods. The present solution can provide echo cancellation by using frequency domain filtering and adjusting its power levels based on statistics gathered during training.

At least one aspect is directed to a method. The method can include one or more processors identifying a plurality of bins. Each bin of the plurality of bins can correspond to a portion of a frequency range of a cable line. The method can include the one or more processors determining that a power level of an echo signal (e.g., residual echo signal) of each of a bin of the plurality of bins and one or more bins adjacent to the bin (e.g., in time or frequency) exceed a respective threshold for the power level. The method can include the one or more processors training an echo canceller of the echo signal for the bin, responsive to the determining.

The method can include the one or more processors increasing a count for training of the echo signal for the bin responsive to the training. The one or more processors can update the power threshold of the bin responsive to comparing the count to a threshold for the count. The method can include the one or more processors training the echo canceller of the echo signal for the bin by adjusting a frequency domain filter of the echo canceller associated with the portion of the frequency range corresponding to the bin.

The method can include the one or more processors comparing the power level of the echo signal of each of the bin and the one or more bins with the respective threshold for the power level of each of the bin and the one or more bins for a plurality of cycles. The plurality of cycles can be within a time period between two (e.g., two or more) consecutive periods of an echo canceller training opportunity (ECTO) of a data over cable service interface specification (DOCSIS) network.

The method can include the one or more processors identifying or inspecting a radius for the one or more bins adjacent to the bin. The method can include the one or more processors selecting a first subset of the one or more bins preceding the bin and a second subset of the one or more bins following the bin. The method can include the one or more processors detecting, responsive to comparing the respective power level of each of the bin and the one or more bins with the respective threshold for the power level of each of the bin and the one or more bins, that the respective power level of the (e.g., residual) echo signal of each of the bin and the one or more bins exceeds the respective threshold for each of the bin and the one or more bins. The method can include the one or more processors classifying, responsive to the detecting implemented within a time period between two (e.g., two or more) consecutive echo canceller training opportunity (ECTO) periods of a data over cable service interface specification (DOCSIS) network, the bin as available for training of the echo signal. The method can include the one or more processors training the echo canceller of the echo signal for the bin responsive to the classifying.

The method can include the one or more processors training, by the one or more processors, one or more echo cancellers of each of the echo signals for each of the one or more bins responsive to determining that the respective power level of the echo signal (e.g., residual echo signal) of each of the bin and the one or more bins exceed the respective threshold for the power level. The method can include the one or more processors increasing a plurality of counts for training the echo canceller of each of the bin and the one or more bins.

The method can include the one or more processors adjusting the power level for the bin responsive to a count for training of the echo signal for the bin during a time period between two consecutive echo canceller training opportunity (ECTO) periods exceeding a threshold for the count. The method can include the one or more processors comparing the adjusted power level of the echo signal (e.g., residual echo signal) of each of the bin and the one or more bins with the respective threshold for the power level.

At least one aspect is directed to a system. The system can include at least one processor coupled with memory and configured to identify a plurality of bins. Each bin of the plurality of bins can correspond to a portion of a frequency range of a cable line. The at least one processor can be configured to determine that a power level of an echo signal (e.g., residual echo signal) of each of a bin of the plurality of bins and one or more bins adjacent to the bin exceed a respective threshold for the power level. The at least one processor can be configured to train an echo canceller of the echo signal for the bin, responsive to the determining.

The at least one processor can be configured to increase a count for training of the echo signal for the bin responsive to the training. The at least one processor can be configured to update the power threshold of the bin responsive to a comparison of the count to a threshold for the count. The at least one processor can be configured to train the echo canceller of the echo signal for the bin by an adjustment of a frequency domain filter of the echo canceller associated with the portion of the frequency range corresponding to the bin.

The at least one processor can be configured to compare the power level of the echo signal of each of the bin and the one or more bins with the respective threshold for the power level of each of the bin and the one or more bins for a plurality of cycles. The plurality of cycles can be within a time period between two (e.g., two or more) consecutive periods of an echo canceller training opportunity (ECTO) of a data over cable service interface specification (DOCSIS) network.

The at least one processor can be configured to identify or inspect a radius for the one or bins adjacent to the bin. The at least one processor can be configured to select a first subset of the one or more bins preceding the bin and a second subset of the one or more bins following the bin.

The at least one processor can be configured to detect, responsive to a comparison of the respective power level of each of the bin and the one or more bins with the respective threshold for the power level of each of the bin and the one or more bins, that the respective power level of the echo signal of each of the bin and the one or more bins exceeds the respective threshold for each of the bin and the one or more bins. The at least one processor can be configured to classify, responsive to the detection implemented within a time period between two (e.g., two or more) consecutive echo canceller training opportunity (ECTO) periods of a data over cable service interface specification (DOCSIS) network, the bin as available for training of the echo signal. The at least one processor can be configured to train the echo canceller of the echo signal for the bin responsive to the classifying.

The at least one processor can be configured to train one or more echo cancellers of each of the echo signals for each of the one or more bins responsive to determining that the respective power level of the echo signal of each of the bin and the one or more bins exceed the respective threshold for the power level. The at least one processor can be configured to increase a plurality of counts for training the echo canceller of each of the bin and the one or more bins.

The at least one processor can be configured to adjust the power level for the bin responsive to a count for training of the echo signal for the bin during a time period. The time period can be a time period between two (e.g., two or more) consecutive echo canceller training opportunity (ECTO) periods exceeding a threshold for the count. The at least one processor can be configured to compare the adjusted power level of the echo signal of each of the bin and the one or more bins with the respective threshold for the power level.

At least one aspect is directed to a non-transitory computer-readable medium storing instructions that, when executed by one or more processors, cause the one or more processors to identify a plurality of bins. Each bin of the plurality of bins can correspond to a portion of a frequency range of a cable line. The instructions, when executed by the one or more processors, can cause the one or more processors to determine that a power level of an echo signal of each of a bin of the plurality of bins and one or more bins adjacent to the bin (e.g., in time or frequency) exceed a respective threshold for the power level. The instructions, when executed by the one or more processors, can cause the one or more processors to train, responsive to the determining, an echo canceller of the echo signal for the bin.

The instructions, when executed by the one or more processors, can cause the one or more processors to increase a count for training of the echo signal for the bin responsive to the training. The instructions, when executed by the one or more processors, can cause the one or more processors to update the power threshold of the bin responsive to a comparison of the count to a threshold for the count.

The instructions, when executed by the one or more processors, can cause the one or more processors to train the echo canceller of the echo signal for the bin by an adjustment to a frequency domain filter of the echo canceller associated with the portion of the frequency range corresponding to the bin. The instructions, when executed by the one or more processors, can cause the one or more processors to compare the power level of the echo signal (e.g., residual echo signal) of each of the bin and the one or more bins with the respective threshold for the power level of each of the bin and the one or more bins for a plurality of cycles. The plurality of cycles can correspond to time periods within a time period between two (e.g., two or more) consecutive periods of an echo canceller training opportunity (ECTO) of a data over cable service interface specification (DOCSIS) network.

### BRIEF DESCRIPTION OF THE DRAWINGS

These and other aspects and features of the present embodiments will become apparent to those ordinarily skilled in the art upon review of the following description of specific embodiments in conjunction with the accompanying figures.

FIG. 1 is a block diagram of a system for training of an echo canceller in upstream signal receivers on quiet sub-carriers.

FIG. 2 is a block diagram illustrating an architecture for a computer system that can be employed to implement elements of the systems and methods described and illustrated herein.

FIG. 3 is a diagram of a process flow for automatic training of an echo canceller in upstream signal receivers on quiet sub-carriers, in accordance with an embodiment of the present solution.

FIG. 4 is a block diagram of an example process flow for filtering or removing an echo signal from the incoming signal, in accordance with an embodiment of the present solution

FIG. 5 is a block diagram of an example process flow for filtering an echo signal, in accordance with an embodiment of the present solution

FIG. 6 illustrates a flow diagram of a method for training of echo canceller in upstream signal receivers on quiet sub-carriers, in accordance with embodiments of the present solution.

### DETAILED DESCRIPTION

The present embodiments shall now be described in detail with reference to the drawings, which are provided as illustrative examples of the embodiments so as to enable those skilled in the art to practice the embodiments and alternatives apparent to those skilled in the art. Figures and examples below are not meant to limit the scope of the present embodiments to a single embodiment, but other embodiments are possible by way of interchange of some or all of the described or illustrated elements, or those apparent to a person of ordinary skill in the art. Certain elements of the present embodiments can be partially or fully implemented using known components, only those portions of such known components that are necessary for an understanding of the present embodiments shall be described, and detailed descriptions of other portions of such known components will be omitted so as not to obscure the present embodiments. Embodiments described in their illustrated contexts should not be limited thereto. For example, embodiments described as being implemented in software should not be limited to such implementation alone, but they can include embodiments implemented in hardware, or combinations of software and hardware, and vice-versa, as will be apparent to those skilled in the art, unless otherwise specified herein. In the present specification, an embodiment showing a singular component should not be considered limiting; rather, the present disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present embodiments encompass present and future known equivalents to the known components referred to herein by way of illustration.

The present solution provides automatic training of a data over cable service interface specification (DOCSIS) 4.0 full duplex (FDX) echo canceller (EC) in upstream signal (US) receivers. The training can take place on low activity (e.g., quiet) upstream subcarriers during low activity subchannel periods, such as, for example periods of Echo Canceller Training Opportunities (ECTO), as specified by DOCSIS 4.0, or time intervals of low activity (e.g., quiet periods) that can occur between the ECTO periods. Automatic training on quiet upstream periods can be scheduled or relied on for FDX amplifiers when the map and signal timings may not be available, and the amplifier is unaware of the signal timings. The present solution can be used on systems, such as HFC implementing DOCSIS 4.0 communication, but also on any other applications in which signal echoes can cause communication difficulties and echo canceller training on frequency bands with low activity (e.g., quiet) received signal can be used to improve the communication.

On applications in which there is a potential correlation between transmitted and received signals, in frequency or time domain, an echo canceller may not be able to train if a substantial amount of upstream communication is present. For example, in the case of DOCSIS 4.0, the system can wait for an ECTO period in order to prevent cancellation depth loss due to correlation between DS signal and the residual noise. ECTO can refer to a continuous period of time during which the US is not transmitted across an FDX sub-band and such quiet periods can be provided for at least 1% of the time. For instance, for an ECTO duration of 400 usec, ECTO is repeated every 40 ms, such that the quiet periods are ensured for at least 1% of the time for each given sub-channel (e.g., frequency bin of the communication line).

Echo canceller (e.g., echo cancellation system) can operate in frequency or in time domain. For example, filtering can be implemented in frequency domain, by adjusting and multiplying particular coefficients for a filter (e.g., filter for the incoming signal). The EC bandwidth can be divided into fixed bandwidth sections that can be referred to as EC bins, such as bins of 100 KHz each. For example, EC bandwidth can be divided into sections of frequency ranges, spanning the EC bandwidth. For example, in DOCSIS 4.0 FDX, the upstream bandwidth (also called FDX band) can be divided in up to three sub-bands. A sub-band can be up to 96 MHz or 192 MHz wide, including guard bands between the sub-bands.

For example, echo canceller input can be in time domain, while internal training and cancelling can be implemented in frequency domain and the EC output (e.g., the residual echo) can be provided in time domain. Internal work in frequency domain can include working in blocks. Time domain samples can be collected (e.g., TD block) and then converted to frequency domain (FD block). A block can then be processed, such that the echo signal is canceled (e.g., subtracted) and the residual component can be converted back to TD block as the output. This same process can then be repeated for all other TD blocks.

On each training period (e.g., every 40 ms) there can be a period during which no US signal is transmitted in the bin. After initial conversion, the present solution can detect quiet periods on bins and can train the bins only when US is not present. The preset solution can automatically detect and recover from sudden echo channel changes. The present solution can operate on each EC bin and can include a power tracking module to estimate or determine (e.g., in frequency domain) the power level of the residual echo for each bin. If the estimated power is below a predefined threshold (e.g., a power threshold) then the EC can train on this bin. Otherwise, the present solution may not train as the correlated residual signal (e.g., usually in upstream communication) is not determined to be sufficiently low. Statistics from the training process can be saved and accumulated per bin. Later on, these statistics can be used to update the power thresholds of each of the bins. After processing all EC bins, the process can repeat for the next FD block. The present solution can also include a power threshold adjustment circuit that can include a background process for updating the power thresholds array. The present solution can use the power tracking module statistics and implement the power threshold adjustments after at least one ECTO period has occurred.

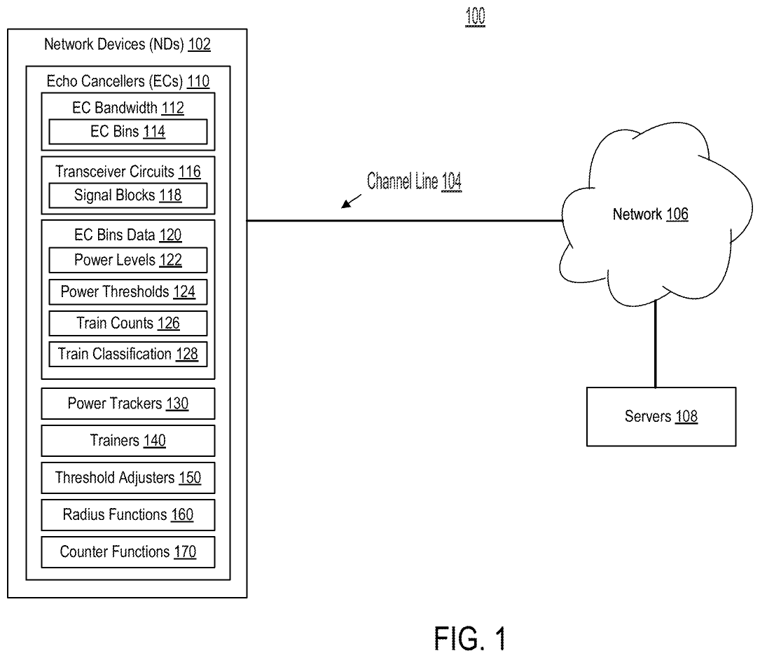

FIG. 1 is a block diagram of a system 100 for training of echo canceller in upstream signal receivers on sub-carriers experiencing low activity in the upstream communication. System 100 can include one or more network devices 102 communicating with one or more remote servers 108, via one or more channel lines 104 connected to a network 106. Network device (ND) 102 can include one or more echo cancellers 110. Each echo canceller (EC) 110 can include or correspond to an EC bandwidth 112 which can be divided or separated into any number of EC bins 114. ND 102 can include one or more transceiver circuits processing signal blocks 118 and one or more EC bins data 120 (e.g., statistics data for EC bins 114) including power levels 122, power thresholds 124, train counts 126 and train classifications 128. ND 102 can include one or more power trackers 130, trainers 140, threshold adjusters 150, radius functions 160 and counter functions 170.

In example system 100, a channel line 104, such as a cable line, can include any medium, such as a wire or line for transmitting signals. Channel line 104 or cable line, can include for example, an HFC line having an interface between two dissimilar mediums (e.g., a fiber optic cable and a coaxial cable). Such interface within the cable line can cause a signal reflection, or an echo signal reflection, that can be mixed with the incoming signal of the ND 102. Transceiver circuits 116 of the ND 102 can receive signal blocks 118 (e.g., in time domain) and transform them to frequency domain. EC 110 of ND 102 can have an EC bandwidth 112 (e.g., a frequency range) divided into any number EC bins 114. For each EC bin 114, a power tracker 130 can monitor power levels 122 with respect to power thresholds 124 of the EC bin 114. Power tracker 130 can determine train classifications (e.g., trainable vs. non-trainable) for each EC bin 114, based on the comparison between power levels 122 with the power thresholds 124 of each EC bins 114 and its neighboring EC bins 114 determined according to a radius around the EC bin 114 by a radius function 160. When the counter functions 170 determines that the EC bin 114 and its neighboring EC bins 114 have had their respective power levels 122 exceeding the respective power thresholds 124 for each of the EC bins 114, for a set number of cycles (e.g., instances of comparison), the counter function 170 can update the train counts 126. In response to the train count 126 exceeding a threshold of a set number of train counts 126 being satisfied consistently (e.g., without interruption), the counter function 170 can update the train count 126.

For instance, an EC bin 114 can be trained responsive to being classified as ‘low power’ for several consecutive FD blocks (history threshold, example 5 blocks in a row). Bin 114 can be classified as ‘low power’ when the bin 114 and its surrounding bins 114 (e.g., within a predefined radius) are determined to be low power, resulting in the ‘training count’ for this bin being increased. For example, a history counter can be used to count for how many FD blocks in a row the bin has been classified as ‘low power’, while another counter can count how many time the bin 114 has been trained. Once a train count 126 exceeds a particular train count 126 (e.g., a particular count value), trainer 140 can determine that the EC bin 114 is in a low activity period (e.g., trainable) and perform training of the EC 110 with respect to the given EC bin 114. For each such training occurrence, a train count 126 of the EC bin 114 is increased. Threshold adjuster 150 can utilize the train count 126 to determine if each of the EC 110 was trained a sufficient number of times for each EC bins 114 and determine if the power threshold 124 for the given EC bin 114 is to be adjusted for the next ECTO period. Threshold adjuster 150 can therefore increase or decrease the power thresholds 124 of each of the EC bins 114, based on their respective train counts 126, in order to adjust (e.g., increase or decrease) the number of EC training events for each EC bin 114 for the upcoming ECTO period. In doing so, system 100 can maintain a desired (e.g., optimal) number of EC training events by the trainer 140 for each individual EC bin 114, thereby ensuring that each EC bin 114 is trained a sufficient amount of times, but not trained on times where upstream is present.

In one example, on every FD block, each bin 114 can be classified as how power or low power, depending on its comparison with the threshold for the bin. The bin energy can be the energy of the residual echo (EC out) in the bin during the FD block. A bin 114 can be classified as “low power” if that particular bin 114 and its surrounding bins 114 within a radius of the bin (e.g., 5 bins surrounding the bin 114 on each side) each have its bin energy below the power threshold for that bin. Otherwise the bin can be classified as high power. On every FD block, each bin can be classified as trainable or not trainable. A bin 114 can be classified as ‘trainable’ if it is defined as ‘low power’ for at least a set (e.g., configurable) number of consecutive FD blocks (e.g., parameter that can be referred as the history threshold). If in any of the previous FD blocks within the history threshold (e.g., set number of tested FD blocks) the bin was classified as ‘high power’, the bin 114 can be set or classified as ‘non-trainable’.

System 100 can include any combination of hardware and software for training of an echo canceller system with respect to upstream signal communication on sub-carriers (e.g., EC bins 114) experiencing low activity in the upstream communication for a given amount of time. System 100 can include any circuitry, device or system providing automated EC training on any number of EC bins 114, corresponding to any portions of frequency or bandwidth of a communication channel (e.g., channel line 104) covered by an EC 110. For instance, system 100 can include a system for automated and periodic reduction, subtraction or cancelling of the echo signals (e.g., signals reflected from the channel lines 104) received by the ND 102.

Channel line 104 can include any medium (e.g., cable or a communication line) for exchange of communication (e.g., data) between the ND 102 and other communication devices (e.g., servers 108) on a network 106. Channel line 104 can include an HFC line, such as a line that includes a portion of a line having a coaxial cable that is interfaced with a network backbone provided by fiber optic lines. Coaxial cable portion of the channel line 104 can be coupled with the ND 102, while the fiber optic line can be some distance away from the ND 102 (e.g., one or more hundreds of meters away from the ND 102). Channel line 104 can include an interface between two or more mediums causing an echo signal to be transmitted towards the ND 102. An echo signal can include, for instance, a delayed and attenuated replica of an original signal that is reflected back and received after bouncing off a surface or discontinuity in a communication channel, such as an interface between a coaxial cable and a fiber optic cable, resulting in undesirable repetition and distortion in data transmissions. Echo signals can occur due to signal reflections and impedance mismatches along the HFC coaxial-fiber line, leading to delayed replicas of transmitted signals, which the EC 110 can seek to eliminate, reduce, attenuate or subtract from the incoming network traffic.

Network 106 include any type of communication network over which network device 102 and/or servers 108 can exchange communications or data. Network 106 can be a global network of interconnected computers and devices allowing sharing of information and communication between various computed devices worldwide. Network 106 can be established using various types of networks, such as local area networks (LANs), wide area networks (WANs), cellular networks, or the Internet. Network 106 can support different communication protocols for email exchange, including the Simple Mail Transfer Protocol (SMTP) for transferring messages between mail servers, the Internet Protocol (IP) for addressing and routing data packets, and Transmission Control Protocol (TCP) for reliable and ordered delivery of data, or any other type of protocols. For instance, network 106 can utilize protocols such as Ethernet for LAN connectivity, Virtual Private Networks (VPNs) for secure communication over public networks, and Domain Name System (DNS) for resolving domain names to IP addresses, television or broadcast network data or signals, or any other type and form of communication that can be transmitted via channel lines 104.

Server 108 can include any combination of hardware and software (e.g., a computing device or a cloud-based service) coupled with a network (e.g., network 106) to establish communication with NDs 102 over one or more channel lines 104 (e.g., HFC coaxial-fiber line). Server 108 can include, for example, a hardware or a software system for managing and delivering network services, data, and resources to the NDs 102, such as internet network traffic, television or broadcast data, digital services or any other network traffic or communication. Server 108 can provide incoming network traffic to the NDs 102, enabling bidirectional data exchange. As channel lines 104 between the server 108 and the ND 102 may include interfaces causing echo, echo signals generated within the network 106 or the channel line 104 can be mixed in with the incoming server 108 traffic.

Network device (ND) 102 can include any combination of hardware and software for network communication via a channel line 104. ND 102 can include any device, system or circuitry for receiving and transmitting network data via an HFC (e.g., coaxial-fiber line) and one or more devices (e.g., servers 108) on a network 106. ND 102 can include, for example, a cable modem device, a cable modem termination system (CMTS), a set-top box for cable television data, a cable headend equipment, a cable amplifier and node, or any other network infrastructure equipment (e.g., routers, switches, optical transmission equipment) or any other device utilizing or supporting DOCSIS communication.

Echo canceller (EC) 110, also referred to as an EC system 110, can include any combination of hardware and software for removal, attenuation, or minimization of echo signals incoming from the network 106 or channel line 104. EC 110 can include a system or a signal processing device or algorithm for adjusting frequency bands of filters (e.g., in transceiver circuits 116) to remove or minimize echo signals from certain EC bins 114 corresponding to sub-carriers of a channel line 104. Since echo signals can occur when a portion of the transmitted signal is reflected back, causing an undesirable repeating effect, EC 110 can utilize power tracker 130 to automatically and continuously monitor and analyze the received signal (e.g., signal blocks 118) to estimate the characteristics of the echo signal. EC 110 can utilize trainer 130 and threshold adjuster 150 to adjust filter model that represents the echo's properties, allowing the EC 110 to subtract the echo signal from the received signal in real-time. EC 110 can subtract or canceling out the unwanted echo components and deliver clear and intelligible incoming data to the receiver.

Echo canceller 110 can include the functionality to adjust, improve or enhance parameters of an EC 110 algorithm or circuitry to improve cancellation of echo signals. For example, EC 110 can adjust parameters, such as filter coefficients of the adaptive filter (e.g., transceiver circuitry 116) which can be periodically and/or continuously adjusted based on the received signal and the estimated echo. This can allow the filters (e.g., circuitry 116) to accurately model and cancel out echoes. In addition, parameters related to convergence speed, step size, and adaptation rate can be monitored and adjusted allow for timely convergence and effective tracking changes in the communication channel.

Echo cancellation bandwidth 112, or EC bandwidth 112, can include any frequency range over which the echo cancellation is provided or applied. For instance, EC bandwidth 112 can include a frequency range corresponding to operational frequency range of the DOCSIS system. EC bandwidth 112 can include any number of frequency sub-carriers or sub-channels covering the EC bandwidth 112 range.

EC bins 114 can include discrete frequency segments, ranges or subdivisions spanning the full spectrum of frequencies of the EC bandwidth 112, allowing the system to precisely analyze and manipulate the signal characteristics for given frequency ranges (e.g., EC bins 114) to implement echo cancellation. EC bins 114 can include or correspond to any portion of an EC bandwidth 112, such as frequency sub-carriers or sub-channels that can be used for echo cancellation within the EC bandwidth 112. EC bandwidth 112 can be split into EC bins 114, which can correspond to any frequency segment or range, such as about 10 KHz, 50 KHz, 100 KHz, 200 KHz or 500 KHz each. EC bins 114 can correspond to one or more individual sub-carriers supported by the channel lines 104. For example, as DOCSIS systems can include an orthogonal frequency division multiplexing (OFDM) features, the communication spectrum can be divided into multiple subcarriers or bins, and the echo cancellation can be applied individually on these subcarriers to mitigate echoes.

Transceiver circuits 116, which can also be referred to as the transceiver circuitry 116, can include any combination of hardware and software for transmitting, receiving and processing network data at the ND 102. Transceiver circuits 116 can include integrated electronic components for transmitting and receiving signals over a channel line 104. Transceiver circuits 116 can facilitate echo cancellation (EC) implementation, processing and capturing the incoming signal, including any echo signals, and implementing filtering and filter adjustments for echo cancellation. Transceiver circuits 116 can include amplifiers, analog-to-digital converters (ADCs) for converting signals from analog to digital, up-tilt circuitry for increasing signal strength of RF signals, digital to analog signals (DACs) for converting digital to analog signals. Transceiver circuit 116 can include a processor, such as a digital signal processor (DSP), to apply an echo cancellation processing, which can determine or model the echo characteristics. Subsequently, the digital-to-analog converters (DACs) convert the processed digital signal back to analog form for output. Transceiver circuit 116 can include a low noise amplifier to amplify weak signals and improve signal strength. Transceiver circuit 116 can include filtering circuitry for signal processing to selectively allow certain frequencies or components of incoming signals to pass through, while isolating, attenuating and blocking other (e.g., undesired) signals.

Signal blocks 118 can include any block, a time duration of one or more incoming signals or sample of incoming data for processing or EC training. Signal block 118 can include a block of incoming signal in time domain (e.g., a duration of signals) across any number of sub-carriers. Signal block 118 can be received in time domain and can be converted to frequency domain for processing. Signal block 118 can include signals or data corresponding to any number of EC bins 114, such as all of EC bins 114 (e.g., corresponding to all sub-carriers to be trained) or a subset of the EC bins 114.

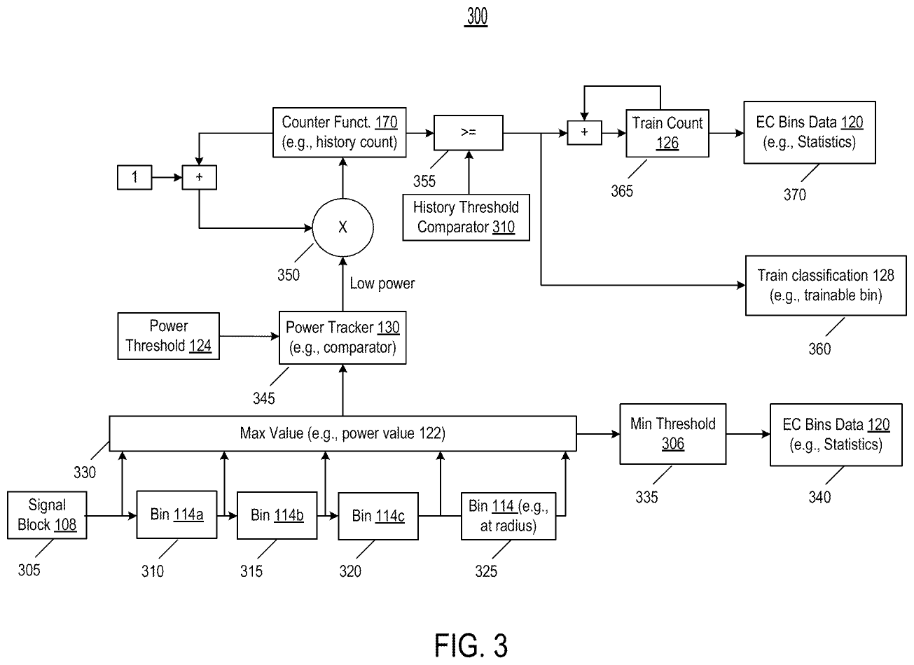

EC bins data 120 (e.g., statistics for EC bins 114) can include any data or statistics for any one or more EC bins 114. EC bins data 120 can include a data structure stored in a storage device (e.g., 225) or memory (e.g., 215) for storing and providing data pertaining to each individual EC bin 114. EC bins data 120 can include one or more arrays of data corresponding to one or more EC bins 114. EC bin data 120 can include power level 122 values, power threshold 124 values, train count 126 values and train classification 128 values or designations for each individual EC bin 114 in the EC bandwidth 112 range. EC bins data 120 can include a minimum threshold 306 (e.g., also referred to as a ‘min threshold’), which can include a minimum power threshold for a single training block in a training cycle (e.g., 80 ms period) for a particular bin 114, as also shown in FIG. 3. Therefore, EC bins data 120 can include minimum power threshold for a given training cycle (per bin 114), where the minimum threshold (e.g., minThresold) can be a minimum of a maximal power of a bin and its surrounding radius of bins (e.g., ‘MaxBinPower’).

Power level 122 can include any value or indication of a power or energy level within a particular EC bin 114. Power level 122 can include a value or indication of a signal strength, signal presence or signal energy or power level, including for example signal amplitude, signal average, or power or voltage values. Power level 122 can correspond to an EC bin 114 or a sub-carrier corresponding to the EC bin 114. Power level 122 can be measured by the transceiver circuit 116. Power level 122 can correspond to an upstream communication signal strength. Power level 122 can correspond to the energy of an echo signal, or a residual echo (e.g., echo canceller output), with respect to an EC bin 114 during a signal block 118.

Power threshold 124 can include any value or indication of a threshold for the power level 122 for an EC bin 114. Power threshold 124 can correspond to a power value with respect to which the power level 122 is compared or measured. Power threshold 124 can be set by a threshold adjuster 150 to trigger a desired number of training occurrences of an EC 110 for a particular EC bin 114 during a time interval or period in between two ECTO periods.

Train count 126 can include a number of occurrences during which a given EC bin 114 has been trained. A train function 140 can implement the train count 126 to maintain the count of instances of training of EC 110 during a particular time duration or period. For instance, train count 126 can correspond to a number of counts that at particular EC bin 114 was trained between two ECTO periods.

Train classification 128 can correspond to a classification of an EC bin 114, such as “trainable” or “not trainable” which the power tracker 130 and/or trainer 140 can determine or establish. For example, a bin 114 can be classified as trainable if its classified as ‘low power’ for a set number (e.g., history threshold) of FD blocks in a row and it can be classified as ‘low power’ if all of its surrounding bins in frequency are below the bin ‘power threshold’ for a given FD block. For example, if a power tracker 130 compares a power level 122 of a particular EC bin 114 (e.g., from a particular received signal block 118) against a current value of the power threshold 124 of the EC bin 114, the power tracker 130 can set the EC bin 114 to a classification or designation of “trainable” or “not trainable.” For example, if a power tracker 130 compares a power level 122 of a particular EC bin 114 and the power levels 122 of the neighboring EC bins 114 (e.g., EC bins 114 surrounding the given EC bin 114 within a radius determined by a radius function 160) against the respective current values of the respective power threshold 124 of each of the EC bins 114, the power tracker 130 can set the EC bin 114 to a classification or designation of “trainable” or “not trainable.”

Trainer 140 can include any combination of hardware and software for training an EC 110 for a given EC bin 114. Trainer 140 can include the functionality for training an Echo Canceller 110 of a ND 110 by comparing the power levels 122 within EC bins 114 to threshold levels 124 for the given EC bins 114. When the power levels 122 of the EC bins 114 exceeds their corresponding thresholds 124, the trainer 140 can initiate training of the corresponding EC 110 by updating the filter coefficients or any parameters for band pass performance and ranges to adapt the EC 110 to adjust, modify or improve its performance in filtering (e.g., canceling) echo signals within that specific EC bin 114 frequency range.

EC training can include the process of adapting and optimizing the parameters of an echo canceller algorithm by utilizing known input signals and their corresponding echoes to improve EC 110 performance. By providing a continuous and period system of utilizing signal blocks 118 to continuously monitor and update the power levels and power thresholds of EC bins 114, the trainer 140 can provide an automatic training of the EC 110, thereby allowing the system 100 to continuously eliminate echo signals from its communications.

Threshold adjuster 150 can include any combination of hardware and software for adjusting the threshold levels 124. Threshold adjuster 150 can include the functionality for determining a desired number or range of trainings that one or more (e.g., each) EC bins 114 should be subjected to in between two ECTO periods. Threshold adjuster 150 can compare the number of training events (e.g., train count 126) for each EC bin 114 with a desired range or value for the number of training occurrences. Threshold adjuster 150 can determine to adjust (e.g., increase or decrease) the power threshold 124 for each given EC bin 114, based on the number of training occurrences within a period (e.g., time frame between two ECTO periods) exceeding or fallings short of the desired value or range. Threshold adjuster 150 can include the functionality to adjust (e.g., increase or decrease) the power threshold 124 value for the EC bin 114 and update it in the EC bins data 120 data structure or array for the next time period of operations.

Radius function 160 can include any combination of hardware and software for determining a radius around an EC bin 114 to identify the neighboring EC bins 114 to include in the determinations. Radius function 160 can include a value designating the number of EC bins 114 below (e.g., corresponding to lower frequency range than) a given EC bin 114 and the number of EC bins 114 above (e.g., corresponding to a higher frequency range than) the given EC bin 114. Radius function 160 can set, determine or include a value of 2 (e.g., for two EC bins 114 below and two EC bins 114 above the EC bin 114 being evaluated or determined). Similarly, radius function 160 can set, determine or include any value for neighboring EC bins 114 below and any same or different value for neighboring EC bins 114 above the given EC bin 114.

Counter function 170 can include any combination of hardware and software for providing counts or counters for the EC 110. Counter function 170 can provide a counter for maintaining a train count 126 for each EC bin 114. Counter function 170 can provide a counter for history values, determinations or evaluations, such as for example a count for a number of times that a particular evaluation (e.g., power level 122 for one or more EC bins 114 being greater than, equal to, or less than, the power threshold 124) has taken place within a time period.

For example, a power tracker 130 can include any combination of hardware and software for tracking and monitoring of EC bins 114. Power tracker 130 can include the functionality for triggering training of the EC 110 with respect to any one or more EC bins 114, based on the EC bins data 120, such as power levels 122, power thresholds 124, train counts 126 and/or train classifications 128. Power tracker 130 can include the functionality for comparing power levels 122 of EC bins 114 against individual power thresholds 124 of the EC bins 114. Power tracker 130 can include the functionality for comparing power levels 122 of EC bins 114 surrounding a given EC bin 114 (e.g., within a given radius) against individual power thresholds 124 of the neighboring EC bins 114.

Power tracker 130 can include the functionality to update the counter function 170. For example, power tracker 130 can increase or zero out the counter function 170. Power tracker 130 can cause the counter 170 to be above a particular threshold, in response to which training can begin. Power tracker 130 can estimate, in frequency domain, the power level of the residual echo for each bin. EC bin data 120 (e.g., statistics) can be captured, saved and accumulated per each EC bin 114. EC bin data 120 can be then used by threshold adjuster 150 to update the power thresholds 124 per each EC bin 114.

After processing the EC bins 114, process can repeat for the next signal block 118, which can be converted in a frequency domain version of the signal block 118 (e.g., FD block). For improved power tracking per each EC bin 114, the solution can consider the nearby (e.g., neighboring) EC bins 114 and their respective power levels 122 and their power thresholds 124. Nearby EC bins 114 can be defined as the EC bins 114 within a specific radius of the current (e.g., specific) EC bin 114 frequency range being tested.

For example, a radius R can include a number of EC bins 114 with frequency ranges (e.g., sub-carriers) below and above the central EC bin 114 being determined in order to determine the current power level 122 of the central EC bin 114. Also, previous power level 122 measurements or data in time of this bin can be considered in order to decide if to enable tracking or not (e.g., the ‘History’ factor). For instance, in order for a specific EC bin 114 to be trainable, all surrounding EC bins 114 within the radius can be determined to have low power levels 122 for several consecutive signal blocks 118.

For example, in each signal block 118, once converted to the frequency domain (FD), EC bins 114 can be categorized or classified as a certain level of power, such as “high power” or “low power” based on the power level 122, such as the maximum energy of the residual echo (EC out) within the bin 114 and its surrounding radius of bins 114. An EC bin 114 can be considered to have “low power” if it has an energy level, which along with all neighboring EC bins 114 (e.g., within given radius determined by radius function 170), falls below the power threshold 124 designated for each of the respective given EC bins 114. In this event, the given EC bin 114 centered in the group of neighboring EC bins 114 can be designated as “trainable,” e.g., when a set number of FD blocks in a row (e.g., history threshold 310) is exceeded upon the threshold being satisfied consistently a set number of times. Meanwhile, other EC bins 114, not designated as “low power” can be identified or classified “not trainable” within the given signal block 118. An EC bin 114 can be classified or categorized as “trainable” if the given EC bin 114 (and its neighboring EC bins 114 within the radius) remain in the “low power” state for a consecutive number of times (e.g., a configurable parameter called History Threshold) for a given number of FD signal blocks 118. For example, if the given EC bin 114 was evaluated as not “low power” (e.g., or high power) in any of the previous set number of signal blocks 118 (e.g., history duration), within the specified history threshold, then such EC bin 114 can be labeled as “not trainable” and may not be trained by the trainer 140. EC Bin 114 can be classified as “low power” in a specific FD block, for example, if that particular bin 114 and all of its surrounding bins 114 (e.g., within a given radius) have power levels that are less than “power threshold 124” of the bin 114, or the power thresholds 124 of each of the respective bin in the radius being inspected or measured.

Power tracker 130 can collect EC bin data 120 (e.g., statistics of each EC bin 114) for the threshold adjuste5 150 to update the power thresholds 124. Statistics for each EC bin 114 can be accumulated for a period of time large enough so a quiet US period is ensured, such as several cycles of evaluating signal blocks 118 for EC bins 114. Such a time period can be referred to as a power threshold adjustment period (PTAP). Collected statistics (e.g., EC bin data 120) can include train counts 126, corresponding to the number of signal blocks 118 (e.g., FD blocks) for which each EC bin 114 was trained during this PTAP period (e.g., one or more cycles of signal block 118 evaluations for EC bins 114). Collected statistics can also include minimum threshold for each signal block 118 (e.g., FD block) per individual EC bin 114, the maximum power level 122 for each EC bin and the maximum power levels 122 for the surrounding neighbors of the EC bin 114 within the radius (e.g., Max Bin power). The Max Bin Power (e.g., maximum or the minimum of it) can be reported for each of the signal blocks 118 per PTAP, per EC bin 114 and included in the EC bin data 120.

Threshold adjuster 150 can implement a power threshold adjustment to update the power threshold 124 for each EC bin 114 that has not converted to a desired number of EC FB block training. This can happen, for example, if the physical echo plant is suddenly changed. (S11 of the south segment changes etc). Adjustment of power threshold can collect EC bins data 120 (e.g., statistics) from power trackers 130 at the end of the PTAP period (e.g., evaluation of all EC bins 114 using the data of a given signal block 118). Adjustment of power threshold 124 can also include identifying, estimating or determining the EC bins 114 that are not trained a sufficient number of times during the PTAP period (e.g., between two ECTO periods). Since in a converged state, downstream echo can be fully canceled and the upstream echo can remain at EC out signal, there can be at least some time periods of the ECTO period for which there was no upstream signal. As such, each EC bin 114 can be expected by the system 100 to be trained, for example, (ECTO)/(Signal Block 180) times the number of signal blocks 108. Threshold adjuster can search for EC bins 114 that were trained fewer times than expected (e.g., including some adjustment margin). For example, threshold adjuster can identify the EC bins 114 within the EC bandwidth 112 for which the train count=(ECTO period)/(Signal Block size)+margin. The power thresholds for such EC bins 114 can be updated to allow an updated (e.g., increased or decreased) number of training cycles in the upcoming PTAB periods.

For instance, power threshold 124 updating for EC bins 114 can be provided as follows:

Power Threshold 124=max (Power threshold (bin)+dUp, Minimum Threhsold (bin)+factor up). Based on this approach, the power threshold 124 can increase at least by dUp (e.g., a certain amount of dB units, such as 9 dB). In the event that the Minimum Threhsold+factorUp is larger than Power threshold (bin)+dUp, the former can be selected. Doing so can speedup power threshold increment and result in faster recovery or adjustment.

As for the EC bins 114 in which train count>=(ECTO period)/(Block size)+margin, the training was sufficient in the previous PTAP period. In such an instance, the power threshold 124 can be updated by adding a factor to the Minimum Threshold for such an EC bin 114, as follows: Power Threshold 124=min threshold+factorUp. The Minimum Threshold can represent the minimal value below which no training could have happened in the previous PTAP.

In some instances, system 100 can determine not to train EC bins 114 rather than to train EC bins 114 on an upstream signal when a sufficient number of trainings took place during the PTAP. For instance, system 100 can utilize the threshold adjuster to maintain the power threshold 124 to be as low as possible, but still high enough to allow sufficient number of trainings of the EC bin 114 in the next PTAP cycle. To implement this, system 100 can utilize a ‘factorUp’ (dB), where minimum threshold can correspond to the value of the power threshold 124 that will allow or cause a minimal sufficient number of trainings to occur on an EC bin 114 during the PTAP. To ensure sufficient training, the system can add several dBs to the threshold level 124 (e.g., usually 15 dB)

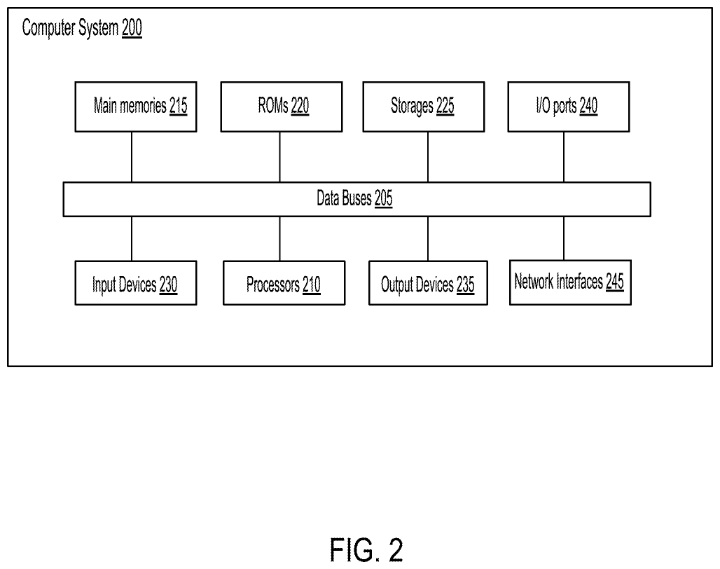

FIG. 2 illustrates a block diagram of an example computer system 200, which can also be referred to as a computing system 200. Computer system 200 can include or be used to implement any computation or processing (e.g., command, protocol or data processing) described herein. Computer system 200 can be included in and run any device (e.g., server) or service or functionality of a network device 102. Computer system 200 can be used for operating or running an ND 102, server 108, or an EC 110, including functions, such as power trackers 130, trainers 140, threshold adjusters 150, radius functions 160, counter functions 170, or any other functionality described herein.

Computing system 200 can include at least one bus data bus 205 or other communication component for communicating information and at least one processor 210 (e.g., processing circuit performing calculations, executing instructions and managing data processing tasks) that can be coupled to the data bus 205 for processing information. Processor 210 can include both a general purpose processor running software, application-specific processing circuitry, and can include processing functionality. Computing system 200 can include one or more processors 210 or processing circuits coupled to the data bus 205 for exchanging or processing data or information. Computing system 200 can include one or more main memories 215, such as a random access memory (RAM), dynamic RAM (DRAM) or other dynamic storage device, which can be coupled to the data bus 205 for storing information and instructions to be executed by the processor(s) 210. Main memory 215 can be used for storing information (e.g., data, computer code, commands or instructions) during execution of instructions by the processor(s) 210.

Computing system 200 can include one or more read only memories (ROMs) 220 or other static storage device coupled to the bus 205 for storing static information and instructions for the processor(s) 210. Storage 225 can include any storage device, such as a solid state device, magnetic disk or optical disk, which can be coupled to the data bus 205 to persistently store information and instructions.

Computing system 200 may be coupled via the data bus 205 to one or more output devices 235, such as speakers or displays (e.g., liquid crystal display or active matrix display) for displaying or providing information to a user. Input devices 230, such as keyboards, touch screens or voice interfaces, can be coupled to the data bus 205 for communicating information and commands to the processor(s) 210. Input device 230 can include, for example, a touch screen display (e.g., output device 235). Input device 230 can include a cursor control, such as a mouse, a trackball, or cursor direction keys, for communicating direction information and command selections to the processor(s) 210 for controlling cursor movement on a display.

Computer system 200 can include input/output ports 240, also referred to as I/O ports 240, can include physical interfaces that facilitate or provide communication between external or peripheral devices and processor(s) 210 and/or memory 215. I/O ports 240 can be connected to data bus 205, allowing the transfer of data between the processor(s) 210, memories 215, and any external devices (e.g., keyboards, mice, printers, and external storage devices). Computer system 200 can also include one or more network interfaces 245 coupled via data buses 205. Network interfaces 245 can include any physical or virtual components enabling communication between the computer system 200 and any external networks (e.g., the Internet). Network interface 245 can provide transfer of data between the processor(s) 210, memories 215 and any external networks.

The processes, systems and methods described herein can be implemented by the computing system 200 in response to the processor 210 executing an arrangement of instructions contained in main memory 215. Such instructions can be read into main memory 215 from another computer-readable medium, such as the storage device 225. Execution of the arrangement of instructions contained in main memory 215 causes the computing system 200 to perform the illustrative processes described herein. One or more processors 210 in a multi-processing arrangement may also be employed to execute the instructions contained in main memory 215. Hard-wired circuitry can be used in place of or in combination with software instructions together with the systems and methods described herein. Systems and methods described herein are not limited to any specific combination of hardware circuitry and software.

Although an example computing system has been described in FIG. 2, the subject matter including the operations described in this specification can be implemented in other types of digital electronic circuitry, or in computer software, firmware, or hardware, including the structures disclosed in this specification and their structural equivalents, or in combinations of one or more of them.

FIG. 3 is a diagram of a process flow of a method 300 for automatic training of echo canceller 110 in upstream signal receivers on quiet sub-carriers, in accordance with an embodiment of the present solution. Method 300 can be implemented by any combination of example systems 100 and 200 of the present solution. Method 300 can include acts 305-370. At 305 an input signal block 108 is received. At 310, a first EC bin 114 is extracted for processing or evaluation. At 315, a second EC bin 114 is extracted for processing or evaluation. At 320, a third EC bin 114 is extracted for processing or evaluation. At 325, any EC bin 114 within a radius of a given EC bin 114 being evaluated is also being extracted for processing. At 330 a max value (e.g., power value 122) can be determined. At 335, a minimum threshold 306 is determined. At 340, EC bins data 120 is updated. At 345, a power tracker 130 compares the max value (e.g., power value 122) is compared against power threshold 124. At 350, for the EC bin 114 that is determined to be low power, a counter function 170 updates a counter value of the history count. At 355, the history threshold comparator 310 compares the history count against the26istoryy threshold for the number of low power determinations of the EC bin 114. At 360, train classification 128 for the EC bin 114 is established (e.g., trainable EC bin), to trigger the EC training for the EC bin 114. At 365, train count 126 is updated. At 370, EC bins data (e.g., statistics) are updated.

At 305, an input signal block (e.g., 108) is received.

The input can include a bin energy for a specific bin. The bin energy can be defined or determined as an absolute value of a fast fourier transform (FFT) of the TD block 118 for a specific bin 114. For bin index K, the energy for bins K-Radius to K+Radius can be passed to bin 114a through bin 114 as in FIG. 3. For example, a time duration of US incoming signal covering a plurality of sub-carriers (e.g., corresponding to multiple EC bins 114 of frequency ranges) can be received. The signal block can include an entire spectral range of the communication (e.g., EC bandwidth 112) which can cover any number of sub-carriers or subchannels supported or provided via a channel line 104. The signal block can be captured in time domain and can include echo signal caused by a reflection in an interface (e.g., connection between a coaxial cable and fiber optic cable in the channel line 104 or a network 106.

At 310, 315, 320 and 325, various EC bins 114 can be extracted for evaluation. For instance, at 310 a first EC bin 114a is extracted for processing or evaluation. The first EC bin 114a can correspond to the EC bin that is being evaluated for training. At 315, a second EC bin 114 can be extracted for processing or evaluation. The second EC bin 114b can correspond to a neighboring EC bin 114 that corresponds to a frequency range the is next to the frequency range of the first EC bin 114a. At 320, a third EC bin 114c can be extracted for processing or evaluation. The third EC bin 114c can correspond to a frequency range that is next to the frequency range of the EC bin 114a, but not directly neighboring the second EC bin 114b. At 325, any EC bin 114 within a radius determined by a radius function with respect to the given EC bin 114a being evaluated for EC training can also be extracted for processing.

For example, if a radius for a bin 114 set to be 10 and the bin 114 being processed is bin number 200 (e.g., K=200), then bins 114 with K=190 through K=210 can be passed as in acts 305 to 325. Max power can be sent by 122 and compared with power threshold for Bin 200. Then, bin 200 can be classified as ‘low power’ or ‘high power’ for this specific FD cycle. If bin 200 is classified ‘low power’ then the history counter for bin 200 can be incremented by one, otherwise history counter for bin 200 is set to zero. This process can then repeat for the next bin k=201, until all bins in the radius are evaluated. Then the determination is made for the bin at the center of the radius (e.g., the bin 200, being evaluated).

At 330, a max value (e.g., power value 122) can be determined. For each individual EC bin 114 (e.g., from the specific or target EC bin 114 being evaluated for training by the EC 110 or any of its surrounding or neighboring EC bins 114) a maximum power value is provided.

At 335, a minimum threshold 306 is determined. The minimum threshold 306 can be the minimum power value from the collection of the EC bins 114 (e.g., target or specific EC bin 114 being evaluated for training and its neighboring EC bins 114) at act 330. The minimum threshold 306 can be provided to the statistics (e.g., EC bin data 120).

At 340, EC bins data 120 is updated. The EC bin data 120 can be updated with the min threshold 306 value. For example, a database corresponding to EC bins data 120 can be updated to include the min threshold 306 value.

At 345, a power tracker 130 can compare the max value (e.g., maximum power value 122 from EC bins 114 gathered at 310-325) to compare it against one or more power thresholds 124. For example, the maximum value from the EC bins 114 can be compared against the power threshold 124 value for the target EC bin 114a. For example, the maximum value from act 330 can be compared against power thresholds 124 of the respective EC bin 114 to which the max value belongs (e.g., if the max value came from EC bin 114b, then the threshold for E bin 114b is used for the comparison). For example, each of the max values of each of the EC bins 114 from acts 310-325 are compared against their respective power threshold 124 values for those respective EC bins 114.

At 350, for the EC bin 114 that is determined to be low power, a counter function 170 updates a counter value of the history count. For example, if the power value 122 is greater than power threshold 124, the EC bin 114 can be indicated or classified as “low power.” For example, if the power value 122 is less than the power threshold 124, the EC bin 114 can be indicated or classified as “low power.” The counter function 170 can provide a counter to increase the count of the “low power” designation, classification or indication for the given EC bin 114 each time this designation, classification or indication is established. This can be done to maintain the count or history of the number of times this designation, classification or indication has occurred.

At 355, the history threshold comparator 310 compares the history count against the history threshold for the number of low power determinations of the EC bin 114. The history threshold comparator 310 can include the functionality (e.g., a counter) to compare how many times the particular EC bin 114 was designated as “low power” in a row. For example, if an EC bin 114 is designated as “low power” a particular number of times (e.g., a count for the “low power” designations over a particular number of cycles has been long enough, where cycle included a new signal block 108 being evaluated), then the history threshold 310 can determine that the given EC bin 114 has been “low power” for a sufficiently long period of time. For example, the history threshold comparator 310 can use a counter determine that the EC bin 114 has been “low power” for 3, 4, 5, 8, 10, 12, 15 or 20 consecutive cycles (e.g., signal block 108 evaluations). History threshold comparator 310 can be a part of a trainer 140 or threshold adjuster 150 and can function with other features of the trainer 140 or threshold adjuster 150 to determine if the given EC bin 114 has been at “low power” designation sufficiently long period of time for it to be retrained.

At 360, train classification 128 for the EC bin 114 is established (e.g., trainable EC bin), to trigger the EC training for the EC bin 114. In response to the history threshold comparator 310 determining that the “low power” designation or classification for the given EC bin 114 has been consistent sufficiently long (e.g., counter of the history threshold comparator exceeding a threshold for history of the low power of the EC bin 114), system 300 can generate or indicate a train classification 128 for the EC bin 114 to indicate the given EC bin 114 as a trainable bin. Trainer 140 can then train the EC 110 on the given EC bin 114 in response to the train classification 128.

At 365, train count 126 is updated. In response to the given EC bin 114 being designated as a trainable bin at 360, the train count 126 for the EC bin 114 can be updated. The train count 126 can therefore maintain a count of the number of times this given EC bin 114 has been trained.

At 370, EC bins data 120 (e.g., statistics) are updated. Any data from acts 305-365 can be included in EC bins data 120 and the statistics (e.g., data structures) for the given EC bin 114 being evaluated and other EC bins 114 can be updated. This same process from acts 305-370 can be repeated for all EC bins 114 of the EC bandwidth 112 across the entire frequency range. This same process can be repeated during the time period between two ECTO periods, during ECTO periods, or across any number of ECTO cycles.

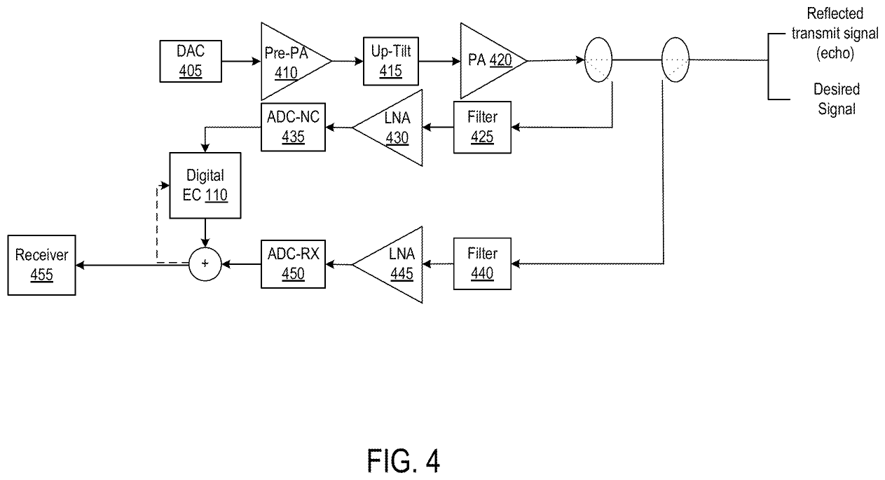

FIG. 4 is a block diagram of an example circuitry 400 for controlling signal to noise ratio (SNR) at EC output in implementation of the echo cancellation, in accordance with an embodiment of the present solution. Circuitry 400 can include, for example, an example of transceiver circuits 116. Circuitry 400 can include any combination of hardware and software for receiving a reflected echo signal (e.g., to be eliminated, attenuated, subtracted or filtered out) and a desired signal (e.g., to be read by the intended receiver 455).

Circuitry 400 can include a digital to analog converter (DAC) 405 which can convert a digital signal into analog output. The output from the DAC 405 can be fed into a pre-power amplifying circuit (e.g., pre-PA) 410 to pre-process (e.g., filter the signal) before sending it to Up-Tilt 415. Up-tilt 415 circuit can perform signal processing for increasing the signal strength or power of RF signal at high frequencies, such as to compensate for signal losses. Output from up-tilt 415 can be input into a PA 420 to amplify the signal and transmit it out, via a channel line 104, towards a device on the network 106.

This transmitted signal can then encounter an interface in the channel line 104 from which a reflected echo signal can be generated. The Echo signal can reflect back to the circuitry 400 (e.g., ND 102). Upon receipt of the echo signal, filter 425 can filter the incoming signal, and feet its output into the low noise amplifier (LNA) 430. LNA 430 can feed its output into an analog to digital converter with no compression (ADC-NC) 435. Digitized output from the ADC-NC 435 can be fed into the digital EC 110.

At the same time, the echo signal can be fed into a filter 440, the output of which can be fed into the LNA 445. The output of the LNA 445 can be fed into the analog to digital converter for receiving (ADC-RX) 450, which can output the actual signal to be processed with the EC out signal of the EC 110 in order to provide a desired signal with reduced, attenuated or eliminated echo, which can be fed into the receiver 455 for further processing and use.

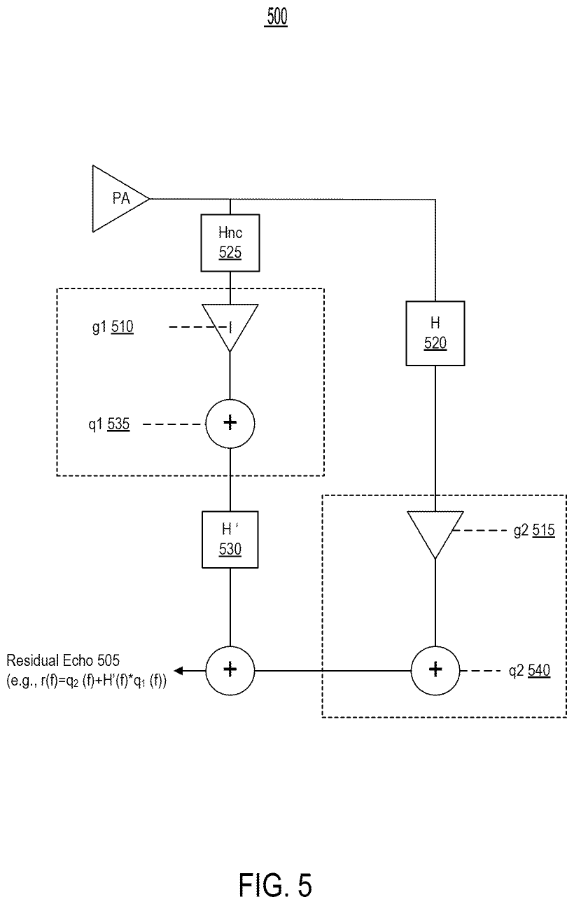

FIG. 5 is a block diagram of an example circuit 500 for filtering or removing an echo signal from the incoming desired signal, in accordance with an embodiment of the present solution. In circuit 500, the residual echo 505 (e.g., r(f) function in the example) can include the Echo Canceller output (EC out) with a digital echo canceller, including no desired signal or any other external noise. The EC out can correspond to the echo signal received by the ND 102.

The power spectral density (PSD) of the residual echo can be expressed using the following Function 1:

$$P S D ( {r}^{2} ) = {{q}_{1}}^{2} ( f ) * {H}^{{′}^{} 2} ( f ) + {{q}_{2}}^{2} ( f )$$

Function 1: Power spectral density of the residual echo (EC out) signal output.

In Function 1, H′ 530 (e.g., H′²(f)) can correspond to a frequency response of the echo canceller, which as shown in Function 2 below, can be computed as a ratio of the squared gain of the echo canceller g₂ 515 (e.g., g₂²) to the squared gain of the adaptive filter g₁ 510 (e.g., g₁²) multiplied by the squared frequency response of the adaptive filter H 520 (e.g., H(f)²), divided by the squared frequency response of the non-causal (NC) H_{nc} 525 adaptive filter (e.g., H_{nc}²(f)), where q₁ 535 (e.g., q₁²(f)) and q₂ 540 (e.g., q₂²(f)) can correspond to analog front end (AFE) noise (flat), and be expressed as follows:

$${H}^{{′}^{} 2} ( f ) = {{g}_{2}}^{2} / {{g}_{1}}^{2} * {H ( f )}^{2} / {{H}_{n c}}^{2} ( f ) ,$$

Function 2: Frequency response of the echo canceller.

In order for the PSD of the residual echo 505 to match the desired signal PSD with some fixed offset signal to noise ratio (SNR), the example circuit 500 can rely on Function 3:

$${{q}_{1}}^{2} ( f ) * {H}^{{′}^{} 2} ( f ) + {{q}_{2}}^{2} ( f ) = U ( f ) / SNR$$

Function 3: PSD of the residual echo matching desired signal PSD with fixed offset SNR.

From the above, the frequency response of the echo canceller can be expressed in terms of the desired PSD and the noise power spectral densities in Function 4, below:

$${H}^{{′}^{} 2} ( f ) = ( U ( f ) / SNR - {{q}_{2}}^{2} ( f ) ) / {{q}_{1}}^{2} ( f )$$

Function 4: frequency response of EC in terms of desired PSD and noise PSDs

Applying the Function 2 with Function 4 (e.g., for H′²(f), above), Function 5 can be used to determine the optimal non-causal (NC) response, as follows:

$${{g}_{2}}^{2} / {{g}_{1}}^{2} * {H ( f )}^{2} / {Hnc}^{2} ( f ) = ( U ( f ) / SNR - {{q}_{2}}^{2} ( f ) ) / {{q}_{1}}^{2} ( f )$$

Function 5: Factoring in Functions 2 and 4

By resolving Function 5, the optimal non-causal response can be expressed as Function 6:

$${Hnc}^{2} ( f ) = {{q}_{1}}^{2} ( f ) * {{g}_{2}}^{2} / {{g}_{1}}^{2} * {H ( f )}^{2} / ( U ( f ) / SNR - {{q}_{2}}^{2} ( f ) )$$

Function 6: Optimal non-causal response.

Therefore, when example circuit 500 is used to alter the NC PSD to match the above expression, example circuit 500 can achieve a flat (e.g., improved) SNR.

In one example, upstream PSD can be assumed to be flat at the RX analog front end (AFE) input (equalized). Then, the desired NC PSD at AFE input can be expressed as Function 7 below:

$$H n {c}^{2} ( f ) = {{q}_{1}}^{2} ( f ) * {{g}_{2}}^{2} / {{g}_{1}}^{2} * {H ( f )}^{2} / ( U / S NR - {{q}_{2}}^{2} ) = Constant ⋆ {H ( f )}^{2}$$

Function 7: Desired NC PSD at AFE

In Function 7, each of the q₁, q₂ and U can be assumed to be flat and not dependent on f. In such an example, a desired signal PSD can be flat and the optimal NC channel PSD at AFE input can match the echo channel PSD with a constant offset.

In one example, a programmable analog filter at the NC path can be used to configure the frequency response of the NC channel (Hnc) so that it can match the above formula. This can be achieved by measuring the Echo canceller coefficients, and by adjusting the analog filter accordingly to get SNR per frequency, as desired. For example, the system can assume that the signal is flat, and the echo channel PSD can be tilted with a slope—‘S’. In this case, the NC filter can have a slope frequency response similar to the echo channel PSD. The EC coefficients give us the echo channel divided by the NC channel. So taking one over these coefficients (e.g., 1/X) can give the desired analog correction to the NC path to achieve the flat SNR when combined with the incoming signal.

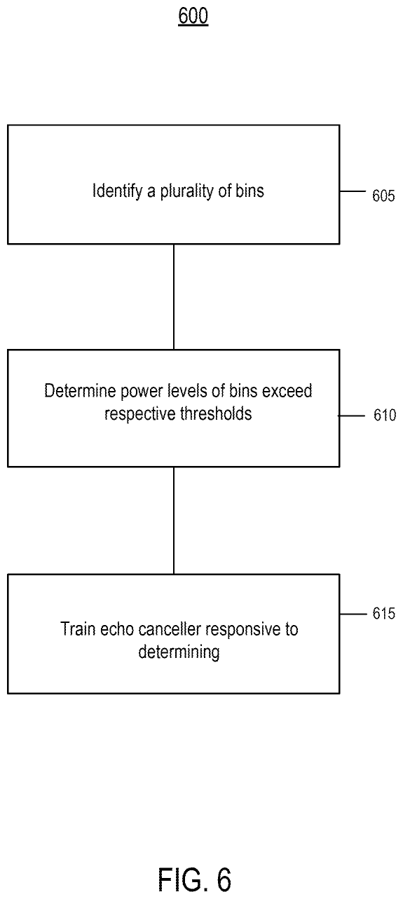

FIG. 6 illustrates a flow diagram of a method for training of echo canceller in upstream signal receivers on quiet sub-carriers, in accordance with embodiments of the present solution. Method 600 can include acts 605-615 that can be performed by example systems and features described and discussed in connection with FIGS. 1-5. At 605, a plurality of bins can be identified. At 610, power levels of bins exceeding respective thresholds can be determined. At 615, an echo canceller can be trained responsive to the determining.

At 605, a plurality of bins can be identified. The method can include identifying, by one or more processors, a plurality of bins (e.g., EC bins). Each bin of the plurality of bins can correspond to a portion of a frequency range of a cable line. Each bin of the plurality of bins can correspond to a range of frequencies of a bandwidth of an echo canceller system or device. For example, echo canceller can include a bandwidth or correspond to a frequency range of up to 10 KHz, 50 KHz, 100 KHz, 150 KHz or 200 KHz. The system can include for example up to 128, 256, 512, 1024, 2048, 4096 or 8192 bins (e.g., EC bins) The bandwidth or frequency range of the transmissions on the cable line can correspond to the bandwidth or frequency range of the echo canceller. The EC bins can total to the bandwidth or frequency range of the cable line or the echo canceller.

The one or more processors can identify a radius for the one or bins adjacent to the bin. The one or more processors can select a first subset of the one or more bins preceding the bin and a second subset of the one or more bins following the bin. For example, a radius function can identify or define the radius for identifying or selecting the neighboring EC bins around the target EC bin being evaluated for EC training. For example, the radius function can identify one bin below (e.g., having a frequency range that precedes the target EC bin) and one bin above (e.g., having a frequency range that follows) the target or certain EC bin being evaluated for training. For example, the radius function can identify two bins below and two bins above the certain EC bin. For example, the radius function can identify at least three, four, five, seven, 10, 15, 20 or more EC bins below or above the target or certain EC bin being evaluated. The radius function can include the number of EC bins below the target EC bin that is the same or different than the number of EC bins above the target EC bin.

At 610, power levels of bins exceeding respective thresholds can be determined. The method can include the one or more processors determining that a power level of an echo signal of each of a bin of the plurality of bins and one or more bins adjacent to the bin exceed a respective threshold for the power level. For example, a power tracker of the EC can measure, monitor or determine power levels of each of the target or certain EC bin being evaluated for training and the neighboring (e.g., one or more EC bins) determined by the radius function at 605. The power tracker can also acquire or identify respective power thresholds (e.g., power threshold values) for each of the target or certain EC bin being evaluated for training and the neighboring EC bins. The power level values for each of these EC bins (e.g., the target bin and the neighboring bins) can be same or different (e.g., vary from bin to bin). Likewise, the power threshold values for each of these EC bins (e.g., the target bin and the neighboring bins) can be same or different (e.g., vary from bin to bin).

The one or more processors can compare the power level of the echo signal of each of the bin and the one or more bins with the respective threshold for the power level of each of the bin and the one or more bins. The comparison can be performed for a plurality of cycles. Each cycle can include a process of analysis of an incoming signal block, using which bins can be tested. Power tracker can compare the power levels of each of the bins (e.g., target EC bin and the neighboring bins) with the respective power thresholds for each of the bins for each individual cycle (e.g., sample of data from the received signal block). The plurality of cycles within a time period can correspond to a time between two consecutive periods of an echo canceller training opportunity (ECTO) of a data over cable service interface specification (DOCSIS) network.

The one or more processors can detect, responsive to comparing the respective power level of each of the bin and the one or more bins with the respective threshold for the power level of each of the bin and the one or more bins, that the respective power level of the echo signal of each of the bin and the one or more bins exceeds the respective threshold for each of the bin and the one or more bins. For example, power tracker can detect or determine that each of the target EC bin and the neighboring EC bins around the target EC bin has its power level that exceeds its respective power threshold, based on the comparison between the power levels and the power thresholds for each of these EC bins.

Responsive to such a determination, the target EC bin being evaluated for training can be identified or classified as low power. A counter for the EC bin can be adjusted (e.g., increased) and then evaluated if the count has identified this particular EC bin as low power for a sufficient number of cycles (e.g., evaluations of consecutive signal blocks). If the counter shows that the target EC bin has been identified as low power for a number of cycles that meet or exceed a threshold (e.g., counter number), the EC bin can be identified or classified as trainable or available for training of the EC on that particular bin.

At 615, an echo canceller can be trained responsive to the determining. The method can include the one or more processors training an echo canceller of the echo signal for the bin, responsive to the determining at 610. The method can include the one or more processors (e.g., trainer of the EC) training the EC of the EC bin responsive to identifying or detecting that the EC bin has been classified or identified as trainable or available for training at 610.

The one or more processors (e.g., counter function) can increase a count for training of the echo signal for the bin responsive to the training. For example, a counter can be increased to indicate the number of times the target bin was trained in a given time period. The time period can be any time period, such as a time duration, one or more signal block processing cycles, or one or more ECTO periods.

The one or more processors can update the power threshold of the bin responsive to comparing the count to a threshold for the count. For example, a threshold adjusted can adjust the power threshold of the bin in response to the count indicating the number of times that the target EC bin has been trained exceeds a threshold. The threshold for the number of times the target EC bin has been trained can correspond to the EC being trained on the given EC bin between two ECTO periods. The threshold can be used to maintain the number of training of the target bin, and any other of the EC bins, within a desired range of training.

The one or more processors can train the echo canceller of the echo signal for the bin by adjusting a frequency domain filter of the echo canceller associated with the portion of the frequency range corresponding to the bin. The one or more processors can classify the bin as available for training of the echo signal. Such a classification can be made or established responsive to the detecting that the respective power level of the echo signal of each of the bin and the one or more bins exceeds the respective threshold for each of the bin and the one or more bins. Such detection can be implemented within a time period between two consecutive echo canceller training opportunity (ECTO) periods of a data over cable service interface specification (DOCSIS) network. The one or more processors (e.g., trainer of the EC) can train the echo canceller of the echo signal for the bin responsive to the classifying.

The one or more processor can train one or more echo cancellers of each of the echo signals for each of the one or more bins. Such training of the one or more echo cancellers of each of the echo signals for each of the one or more bins can be implemented responsive to determining that the respective power level of the echo signal of each of the bin and the one or more bins exceed the respective threshold for the power level. The training can be implemented responsive to determining that the respective power level of the echo signal of each of the bin and the one or more bins exceed the respective threshold for the power level more than a threshold number of times in a row (e.g., consistently for a plurality of processing cycles of a plurality of signal blocks).

The one or more processors can increase, responsive to the training, a plurality of counts for training the echo canceller of each of the bin and the one or more bins. The one or more processors can adjust the power level for the bin responsive to a count for training of the echo signal for the bin during a time period between two consecutive echo canceller training opportunity (ECTO) periods exceeding a threshold for the count. The one or more processors can compare the adjusted power level of the echo signal of each of the bin and the one or more bins with the respective threshold for the power level.

Having now described some illustrative implementations, it is apparent that the foregoing is illustrative and not limiting, having been provided by way of example. In particular, although many of the examples presented herein involve specific combinations of method acts or system elements, those acts and those elements can be combined in other ways to accomplish the same objectives. Acts, elements and features discussed in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation or embodiment, and references to “an implementation,” “some implementations,” “one implementation” or the like are not necessarily mutually exclusive and are intended to indicate that a particular feature, structure, or characteristic described in connection with the implementation may be included in at least one implementation or embodiment. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

When an element is referred to herein as being “connected” or “coupled” to another element, it is to be understood that the elements can be directly connected or coupled the other element, or have intervening elements present between the connected or coupled elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

When an element is referred to herein as being “disposed” beneath or above a particular element, it is to be understood that the elements can be directly located or positioned above or below the other element, or have intervening elements present between the two elements. In contrast, when an element is referred to as being “directly disposed” on or below another element, it should be understood that no intervening elements are present in the “direct” disposition between the elements. However, the existence of a direct disposition does not exclude other disposition, in which intervening elements may be present.

While operations are depicted in the drawings in a particular order, such operations are not required to be performed in the particular order shown or in sequential order, and all illustrated operations are not required to be performed. Actions described herein can be performed in a different order. The separation of various system components does not require separation in all implementations, and the described program components can be included in a single hardware or software product.

What is claimed is:

1. A method comprising,
identifying, by one or more processors, a plurality of bins, each bin of the plurality of bins corresponding to a portion of a frequency range of a cable line;
determining, by the one or more processors, that a power level of an echo signal of each of a bin of the plurality of bins and one or more bins adjacent to the bin exceed a respective threshold for the power level;
training, by the one or more processors, an echo canceller of the echo signal for the bin, responsive to the determining.

2. The method of claim 1, comprising:
increasing, by the one or more processors, a count for training of the echo signal for the bin responsive to the training; and
updating, by the one or more processors, the power threshold of the bin responsive to comparing the count to a threshold for the count.

3. The method of claim 1, comprising:
training, by the one or more processors, the echo canceller of the echo signal for the bin by adjusting a frequency domain filter of the echo canceller, the frequency domain filter associated with the portion of the frequency range corresponding to the bin.

4. The method of claim 1, comprising:
comparing, by the one or more processors, the power level of the echo signal of each of the bin and the one or more bins adjacent to the bin with the respective threshold for the power level of each of the bin and the one or more bins for a plurality of cycles, the plurality of cycles within a time period between two consecutive periods of an echo canceller training opportunity (ECTO) of a data over cable service interface specification (DOCSIS) network.

5. The method of claim 1, comprising:
identifying, by the one or more processors, a radius for the one or bins adjacent to the bin; and
selecting, by the one or more processors, a first subset of the one or more bins preceding the bin and a second subset of the one or more bins following the bin.

6. The method of claim 1, comprising:
detecting, by the one or more processors responsive to comparing the respective power level of each of the bin and the one or more bins with the respective threshold for the power level of each of the bin and the one or more bins, that the respective power level of the echo signal of each of the bin and the one or more bins exceeds the respective threshold for each of the bin and the one or more bins; and
classifying, by the one or more processors, responsive to the detecting implemented within a time period between two consecutive echo canceller training opportunity (ECTO) periods of a data over cable service interface specification (DOCSIS) network, the bin as available for training of the echo signal; and
training, by the one or more processors, the echo canceller of the echo signal for the bin responsive to the classifying.

7. The method of claim 1, comprising:
training, by the one or more processors, one or more echo cancellers of each of the echo signals for each of the one or more bins responsive to determining that the respective power level of the echo signal of each of the bin and the one or more bins adjacent to the bin exceeds the respective threshold for the power level; and
increasing, by the one or more processors, a plurality of counts for training the echo canceller of each of the bin and the one or more bins, responsive to the training.

8. The method of claim 1, comprising:
adjusting, by the one or more processors, the power level for the bin responsive to a count for training of the echo signal for the bin during a time period between two consecutive echo canceller training opportunity (ECTO) periods exceeding a threshold for the count; and
comparing, by the one or more processors, the adjusted power level of the echo signal of each of the bin and the one or more bins with the respective threshold for the power level.

9. A system, comprising:
at least one processor coupled with memory and configured to:
identify a plurality of bins, each bin of the plurality of bins corresponding to a portion of a frequency range of a cable line;
determine that a power level of an echo signal of each of a bin of the plurality of bins and one or more bins adjacent to the bin exceed a respective threshold for the power level;
train an echo canceller of the echo signal for the bin, responsive to the determining.

10. The system of claim 9, wherein the at least one processor is configured to:
increase a count for training of the echo signal for the bin responsive to the training; and
update the power threshold of the bin responsive to a comparison of the count to a threshold for the count.

11. The system of claim 9, wherein the at least one processor is configured to:
train the echo canceller of the echo signal for the bin by an adjustment of a frequency domain filter of the echo canceller, the frequency domain filter associated with the portion of the frequency range corresponding to the bin.

12. The system of claim 9, wherein the at least one processor is configured to:
compare the power level of the echo signal of each of the bin and the one or more bins adjacent to the bin with the respective threshold for the power level of each of the bin and the one or more bins for a plurality of cycles, the plurality of cycles within a time period between two consecutive periods of an echo canceller training opportunity (ECTO) of a data over cable service interface specification (DOCSIS) network.

13. The system of claim 9, wherein the at least one processor is configured to:
identify a radius for the one or bins adjacent to the bin; and
select a first subset of the one or more bins preceding the bin and a second subset of the one or more bins following the bin.

14. The system of claim 9, wherein the at least one processor is configured to:
detect, responsive to a comparison of the respective power level of each of the bin and the one or more bins with the respective threshold for the power level of each of the bin and the one or more bins, that the respective power level of the echo signal of each of the bin and the one or more bins exceeds the respective threshold for each of the bin and the one or more bins; and
classify, responsive to the detection implemented within a time period between two consecutive echo canceller training opportunity (ECTO) periods of a data over cable service interface specification (DOCSIS) network, the bin as available for training of the echo signal; and
train the echo canceller of the echo signal for the bin responsive to the classifying.

15. The system of claim 9, wherein the at least one processor is configured to:
train one or more echo cancellers of each of the echo signals for each of the one or more bins responsive to determining that the respective power level of the echo signal of each of the bin and the one or more bins adjacent to the bin exceeds the respective threshold for the power level; and
increase a plurality of counts for training the echo canceller of each of the bin and the one or more bins.

16. The system of claim 9, wherein the at least one processor is configured to:
adjust the power level for the bin responsive to a count for training of the echo signal for the bin during a time period between two consecutive echo canceller training opportunity (ECTO) periods exceeding a threshold for the count; and
compare the adjusted power level of the echo signal of each of the bin and the one or more bins with the respective threshold for the power level.

17. A non-transitory computer-readable medium storing instructions that, when executed by one or more processors, cause the one or more processors to:
identify a plurality of bins, each bin of the plurality of bins corresponding to a portion of a frequency range of a cable line;
determine that a power level of an echo signal of each of a bin of the plurality of bins and one or more bins adjacent to the bin exceed a respective threshold for the power level;
train, responsive to the determining, an echo canceller of the echo signal for the bin.

18. The non-transitory computer readable medium of claim 17, wherein the instructions, when executed by the one or more processors, cause the one or more processors to:
increase a count for training of the echo signal for the bin responsive to the training; and
update the power threshold of the bin responsive to a comparison of the count to a threshold for the count.

19. The non-transitory computer readable medium of claim 17, wherein the instructions, when executed by the one or more processors, cause the one or more processors to:
train the echo canceller of the echo signal for the bin by an adjustment to a frequency domain filter of the echo canceller, the frequency domain filter associated with the portion of the frequency range corresponding to the bin.

20. The non-transitory computer readable medium of claim 17, wherein the instructions, when executed by the one or more processors, cause the one or more processors to:
compare the power level of the echo signal of each of the bin and the one or more bins adjacent to the bin with the respective threshold for the power level of each of the bin and the one or more bins for a plurality of cycles, the plurality of cycles within a time period between two consecutive periods of an echo canceller training opportunity (ECTO) of a data over cable service interface specification (DOCSIS) network.
